(19) United States
(12) Patent Application Publication
(10) Pub. No.: US 2007/0099127 A1
(43) Pub. Date: May 3, 2007

(54) Compact integrated capacitor

(76) Inventor: Bohumil Lojek, Colorado Springs, CO (US)

Correspondence Address: SCHNECK & SCHNECK, P.O. BOX 2-E, SAN JOSE, CA, 95109-0005, US

(21) Appl. No.: 11/266,453

(22) Filed: Nov. 3, 2005

(51) Int. Cl. G03F 7/26

(52) U.S. Cl. 430/313; 430/311

(57) ABSTRACT

An interdigitized, single layer capacitor with a narrow interplate channel and a method for forming the same is disclosed. The narrow interplate channel is formed using a method which provides for a narrower interplate channel than can be produced using standard photolithographic techniques.

### FIELD OF THE INVENTION

The present invention relates generally to a process for fabricating an integrated circuit (IC) structure, and more specifically to a process for forming and manufacturing integrated circuit capacitors.

### BACKGROUND INFORMATION

A continuing demand for more reliable integrated circuits that take up less space and use less energy requires that circuit elements be designed to perform a desired function while using as little space is possible. Additionally, to meet this demand, data must be stored in a highly energy efficient manner.

As an overall demand is for smaller components, increasing capacitance by increasing a surface area of charge plates and reducing a distance between them has been one trend for solving a problem of potential unreliable data storage. Even so, physical limits of photolithography have limited progress with respect to reducing the distance between the charge plates of the capacitor.

Four governing performance parameters of a photolithographic system are limit-of-resolution, Lᵣ, level-to-level alignment accuracy, depth-of-focus, and throughput. For purposes of this discussion, limit-of-resolution, level-to-level alignment, and depth-of-focus are physically constrained parameters.

Typical photolithographic techniques are limited by physical constraints of a photolithographic system involving actinic radiation wavelength, λ, and geometrical configurations of projection system optics. According to Rayleigh's criterion,

$${L}_{r} = \frac{0.61 λ}{NA}$$

where NA is the numerical aperture of the optical system and is defined as NA=n sin α, where n is the index of refraction of a medium which the radiation traverses (usually air for this application, so n≅1) and α is a half-angle of the divergence of the actinic radiation. For example, using deep ultraviolet illumination (DUV) with λ=193 nm, and NA=0.7, the lower limit of resolution is 168 nanometers (1680 Å). Techniques such as phase-shifted masks can extend this limit downward, but photomasks required in this technique are extremely expensive. This expense becomes greatly compounded with a realization that an advanced semiconductor process may employ more than 25 photomasks.

Along with the limit-of-resolution, the second parameter, level-to-level alignment accuracy, becomes more critical as feature sizes on photomasks decrease and a total number of photomasks increases. For example, if photomask alignment by itself causes a reduction in device yield to 95% per layer, then 25 layers of photomask translates to a total device yield of 0.95²⁵=0.28 or 28% yield (assuming independent errors). Therefore, a more complicated mask, such as a phase-shifted mask, is not only more expensive but device yield can suffer dramatically.

Further, although the numerical aperture of the photolithographic system may be increased to lower the limit-of-resolution, the third parameter, depth-of-focus, will suffer as a result. Depth-of-focus is inversely proportional to NA². Therefore, as NA increases, limit-of-resolution decreases but depth-of-focus decreases more rapidly. The reduced depth-of-focus makes accurate focusing more difficult especially on non-planar features such as “Manhattan Geometries” becoming increasingly popular in advanced semiconductor devices.

Therefore, what is needed is a way to increase IC device density and efficiency without having to rely on costly and unreliable next generation advanced photolithography techniques.

### SUMMARY

The present invention is an improved integrated circuit capacitor and its method of manufacture capable of producing features significantly less than the limit of resolution of a photolithographic tool. Prior art IC capacitors are limited with respect to plate spacing by an inherent limitation in photolithographic image resolution; as features become smaller, they become less defined until they can no longer meet the tolerances required for accurate and precise feature definition. An exemplary embodiment of the present invention overcomes this photolithographic limitation by utilizing a fabrication method using nitride spacers to create an interdigitized capacitor with charge plates that are separated by dielectric spacing that is narrower than photolithographic technology will allow. This reduced inter-plate spacing provides a proportional increase in capacitance without increasing footprint requirements. When incorporated into a floating gate memory cell, the present invention offers a significant advance in memory cell reliability by allowing an increase in charge stored on a gate capacitor without increasing the physical size of the capacitor.

Additionally, features are self-aligning, eliminating mask alignment errors and the subsequent yield losses that result from such errors.

### BRIEF DESCRIPTION OF THE DRAWINGS

FIGS. 1A-1H illustrate various exemplary cross sections during various fabrication steps of an exemplary IC capacitor.

FIG. 2 is a top view of a floating-gate memory cell incorporating the exemplary capacitor.

### DETAILED DESCRIPTION

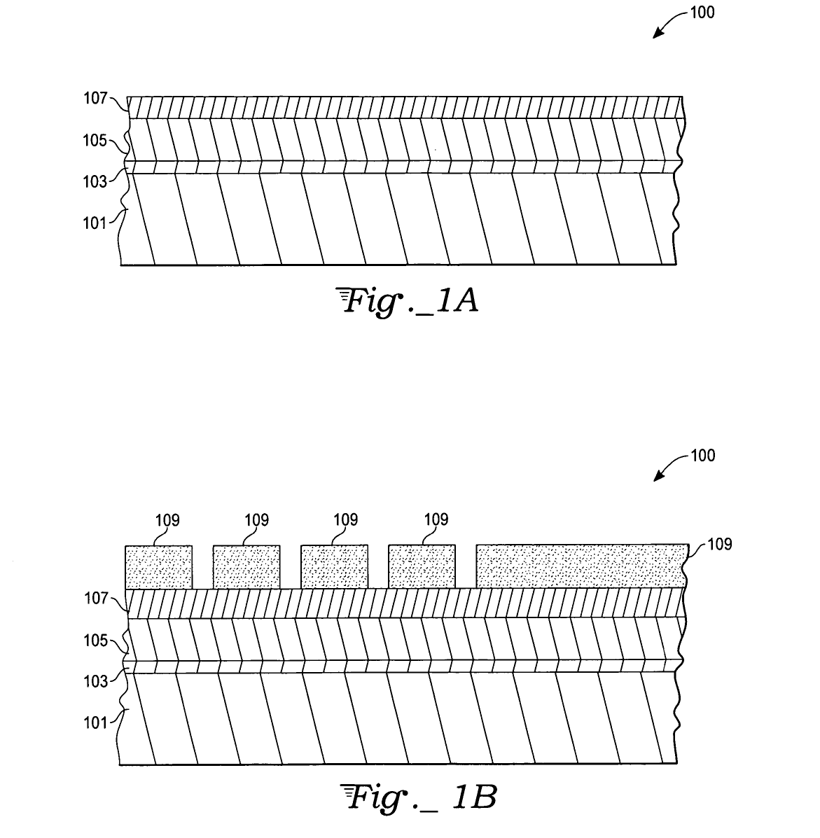

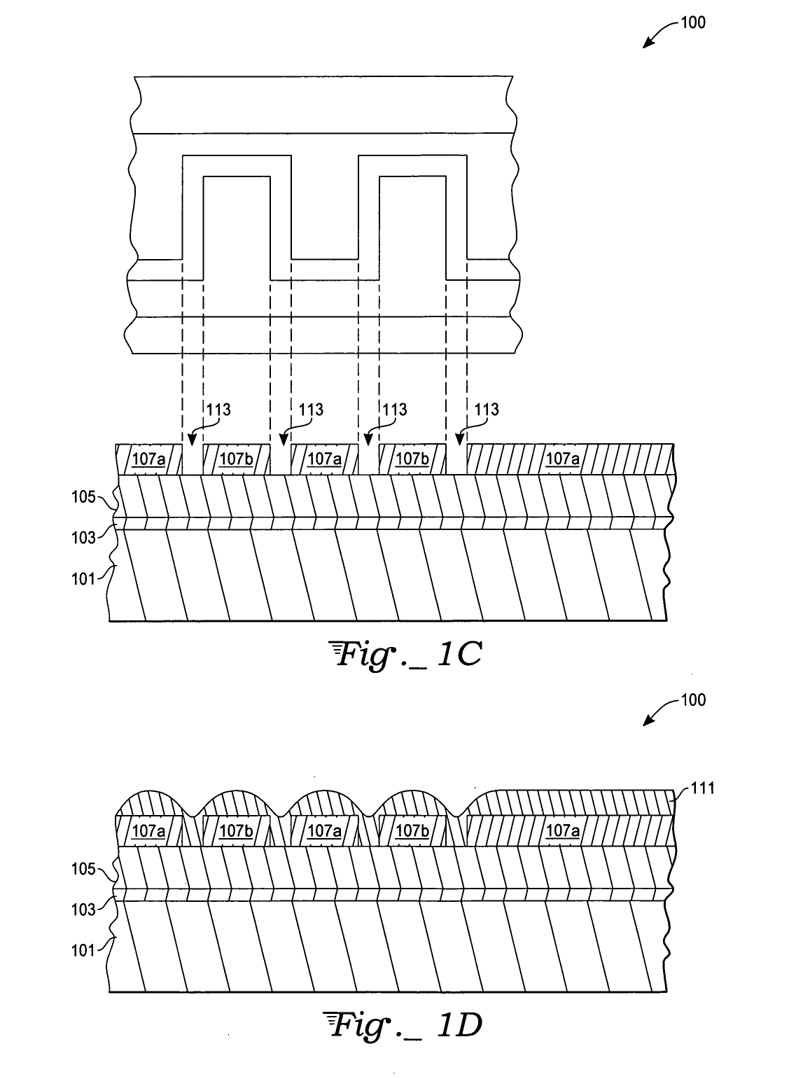

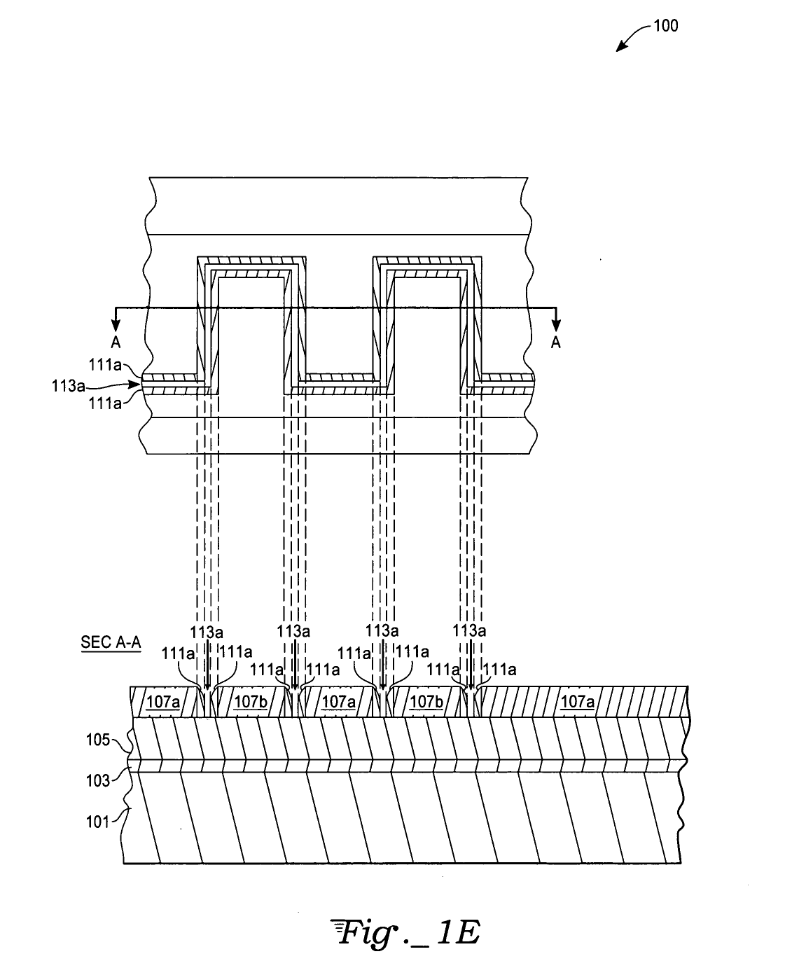

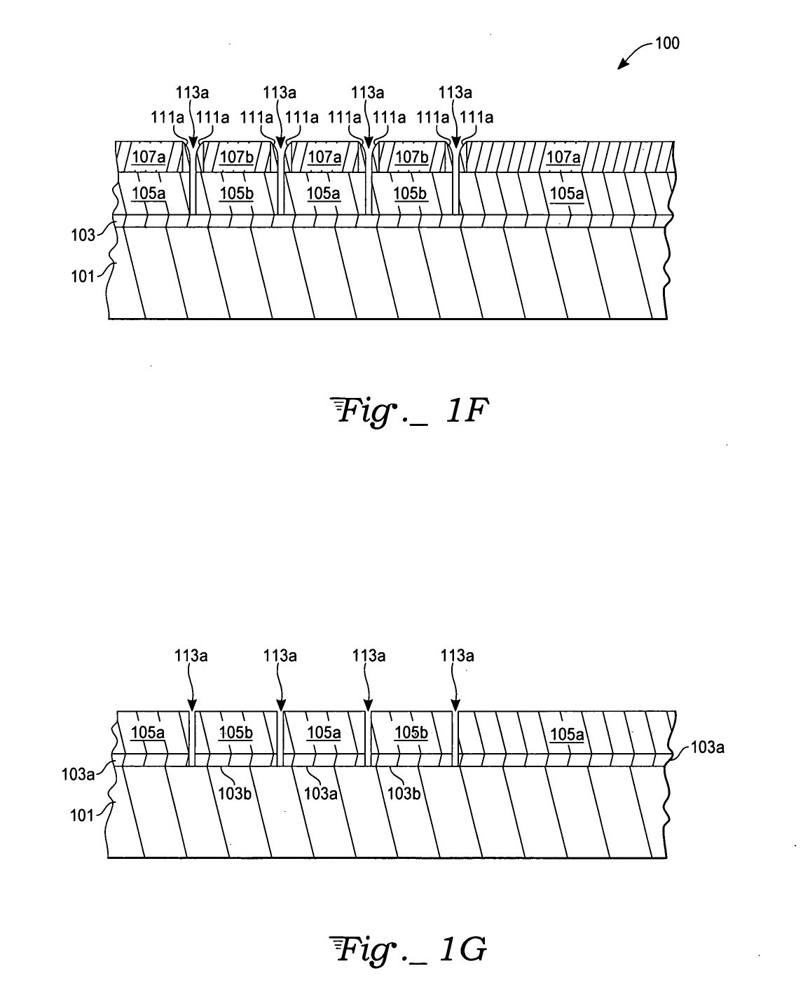

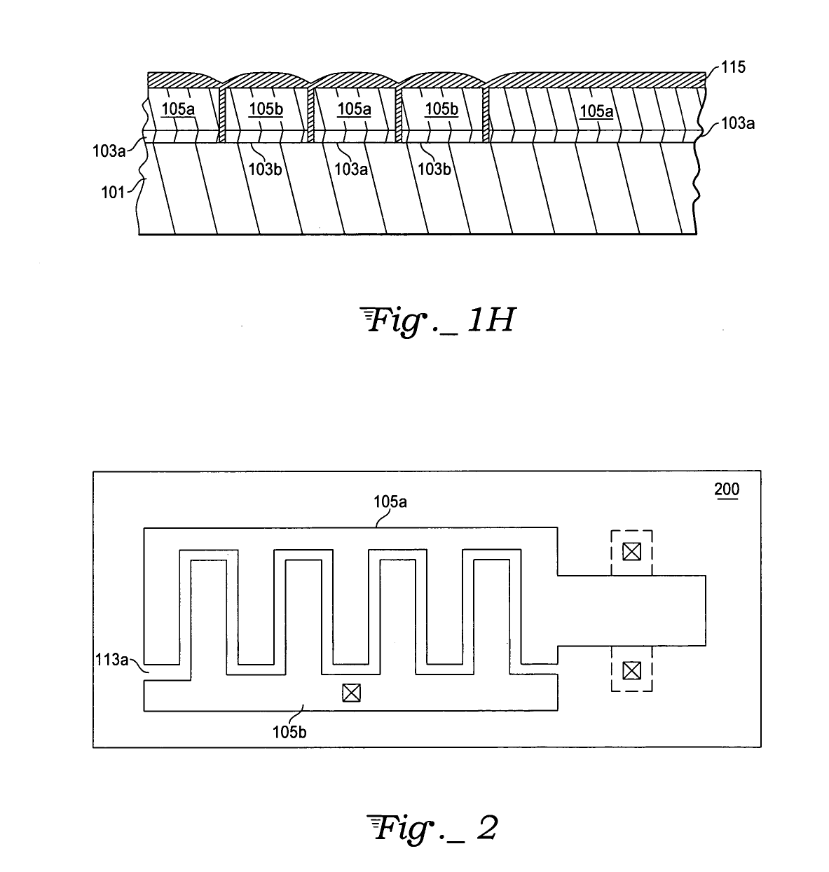

With reference to FIG. 1A an exemplary multi-layer structure 100,includes a substrate 101, a first dielectric layer 103,a semiconductor layer 105,and a second dielectric layer 107,comprising the starting layers for a fabricated compact capacitor. An alternative embodiment uses an insulative substrate, eliminating a need for the first dielectric layer 103. In a specific exemplary embodiment, the first dielectric layer 103 is a thermally grown silicon dioxide, selected to be 60-70 angstroms thick, grown on the substrate 101, and forms an extension of a gate oxide layer of a floating gate memory cell, described infra, with respect to FIG. 2. In this embodiment, the substrate 101 is silicon (e.g., either doped or intrinsic), although one skilled in the art will appreciate that many other semiconductors, such as compound semiconductors, and insulators-such as silicon-on-insulator (SOI), quartz, or glass, can be used. In another exemplary embodiment, the multi-layer structure is an oxygen implanted silicon (SIMOX) wafer with a dielectric layer formed on the outer silicon surface. In an exemplary embodiment, the semiconductor layer 105 is selected to be approximately 1.5 microns thick, is selected to be polysilicon or amorphous silicon, and is formed by chemical vapor deposition (CVD), a fabrication method well established in the art. The second dielectric layer 107 is, for example, a CVD silicon dioxide layer formed by the pyrolytic oxidation of tetraethylorthosilane (TEOS).

With respect to FIG. 1B the multi-layer structure 100 has a photolithographic mask 109 applied and patterned over the second dielectric layer 107. In a specific exemplary embodiment, the gaps in the photolithographic mask 109 are selected to be at or near a minimum feature size available for the photolithography pattern transfer device employed. One skilled in the art will appreciate that the gaps in the photolithographic mask 109 will vary with a combination of wavelength associated with equipment used, the height to width ratio of the channel, and the material selected for the second dielectric layer 107.

With respect to FIG. 1C, the photoresist mask 109 and portions of the second dielectric layer 107 have been removed. A plurality of patterned dielectric plates 107a, 107b are what remain after the second dielectric layer 107 is etched and define a serpentine path 113. The serpentine path 113 is etched in the patterned dielectric plates 107a 107b, the contours of which are visible in the plan view of FIG. 1C.

With respect to FIG. 1D, the multi-layer structure 100 with the serpentine path 113 etched in the second dielectric layer 107, leaving the patterned dielectric plates 107a, 107b, is covered by a third dielectric layer 111 deposited by, for example, CVD. In a specific exemplary embodiment, the third dielectric layer 111 is a conformally deposited nitride layer. A nitride is selected in order to establish a high differential rate of etching for a subsequent processing step, described infra. An application of the conformal nitride layer results in a substantially sinusoidally shaped deposit, where the troughs are self-aligned with the center of the serpentine path 113, visible in FIG. 1D.

With respect to FIG. 1E, the third dielectric layer 111 has been anisotropically etched, leaving a plurality of dielectric spacers 111a. A selective etch cycle, for example, reactive ion etching (RIE), is selected to result in a higher etch rate of the third dielectric layer 111 as compared to the etch rate of the patterned dielectric plates 107a, 107b. The resistant, substantially sinusoidally shaped deposition, coupled with the high etch resistance of patterned dielectric plates 107a, 107b, and the etch characteristics of RIE result in the center of each trough being eroded at a higher rate than its corresponding crests. The etch time, along with a high-selectivity etchant, is selected to result in an incomplete etch of the third dielectric layer 111, leaving the plurality of dielectric spacers 111a adjacent to and contiguous with sidewalls of the patterned dielectric plates 107a, 107b; the plurality of dielectric spacers 111a, defining and aligning a narrow serpentine path 113a. One significant advantage of using dielectric spacers is that, where the channels defined by the photolithographic mask 109(FIG. 1B) are limited by the photolithography technology employed, the dielectric spacers 111a mask the lateral portions of the serpentine path 113 to create the narrow serpentine path 113a that has a smaller width dimension than can be achieved by using photolithography. A further advantage of this dielectric spacer method is that the spacers are self-aligning, which eliminates yield losses associated with errors incident to additional photolithography processes and alignment issues.

With respect to FIG. 1F, the narrow serpentine path 113a defines the pattern to be etched in the semiconductor layer 105,which, after selective etching—using, for example, a dry etch process such as RIE—leaves a plurality of capacitor plates 105a, 105b. For this step, the reactants are selected to erode the semiconductor layer 105 at a much higher rate than the patterned dielectric plates 107a, 107b, and the plurality of the dielectric spacers 111a. In a specific exemplary embodiment, the third dielectric layer 111 was deposited and etched to leave a 0.04 micron wide dielectric spacer 111a on each side of the channel. The subsequent etch cycle, using the patterned dielectric plates 107a, 107b together with the plurality of dielectric spacers 111a as a mask leaves, for example, a 0.10 micron channel or smaller (e.g., 50 Å or less is feasible), which results in a proportional increase in the capacitance of the final apparatus when compared to a capacitor manufactured with dimensions of the serpentine path 113. A skilled practitioner will recognize that the feature size limits will vary with different photolithographic methods, and that photolithographic equipment with higher resolution can be used to form patterned layers with features even smaller than those created in the exemplary embodiment described herein. Alternatively, etch times, rates, and etchants may be chosen to etch less of the plurality of dielectric spacers 111a, resulting in an even narrower interplate channel in the narrow serpentine path 113a.

With respect to FIG. 1G, what remains of the multi-layer structure 100 after removal of the plurality of dielectric spacers 111a and the patterned dielectric plates 107a, 107b, are the plurality of capacitor plates 105a, 105b, the narrow etched channel 113a, and the substrate 101.The patterned dielectric plates 107a, 107b, and the plurality of dielectric spacers 111a are removed in a process step which also etches the narrow etch channel 113a through the first oxide layer 103, leaving first oxide plates 103a, 103b. Note that there is no requirement to completely etch through the first oxide layer 103. In a specific exemplary embodiment, a dry etch process with an etchant selected to be reactive to silicon dioxide and silicon nitride, and not reactive to silicon is used. In another specific exemplary embodiment, the plurality of dielectric spacers 111a a and the patterned dielectric plates 107a, 107b are removed, and the first oxide layer 103 is etched using a wet etch wherein an etchant that is selective to silicon nitride and silicon dioxide, but not to silicon, is employed.

With respect to FIG. 1H, a capacitor formed from the multi-layer structure 100 (FIG. 1A) is covered with a conformal dielectric fill layer 115 filling all of the interdigital channels and providing a protective overcoat for the completed compact capacitor. The conformal dielectric fill layer 115 is deposited using, for example, CVD. The conformal dielectric fill layer 115 may then be etched back to be coplanar with an uppermost surface of the plurality of capacitive plates 105a, 105b. The etch-back may be accomplished by, for example, chemical mechanical planarization (CMP).

With reference to FIG. 2, a top view of a floating gate memory cell incorporates an exemplary embodiment of the present invention. The conformal dielectric layer 115 is not shown to illustrate the narrow serpentine path 113a and the capacitive plates 105a, 105b.

In the foregoing specification, the present invention has been described with reference to specific embodiments thereof. It will, however, be evident to a skilled artisan that various modifications and changes can be made thereto without departing from the broader spirit and scope of the invention as set forth in the appended claims. For example, skilled artisans will appreciate that other types of semiconducting and insulating materials other than those listed may be employed. Additional particular process fabrication and deposition techniques, such as low pressure chemical vapor deposition (LPCVD), ultra-high vacuum CVD (UHCVD), spin-on glass (SOG), and low pressure tetra-ethoxysilane (LPTEOS) may be readily employed for various layers and still be within the scope of the present invention. For example, the substrate may also be comprised of an insulator, as in silicon-on-insulator (SOI) material, which may present opportunities to develop alternative embodiments of the present invention using alternative materials and methods enabled by the present disclosure. The specification and drawings are, accordingly, to be regarded in an illustrative rather than a restrictive sense.

What is claimed is:

1. A method for fabricating an integrated circuit device, the method comprising:
forming a first dielectric layer over a semiconductor substrate;
forming a semiconductor layer over the first dielectric layer;
forming a second dielectric layer over the semiconductor layer;
etching the second dielectric layer to produce a substantially serpentine channel that extends through the second dielectric layer, the substantially serpentine channel creating two interdigitized features in the second dielectric layer;
depositing a third dielectric layer over the second dielectric layer to fill the substantially serpentine channel, the third dielectric layer having an etch rate dissimilar to an etch rate of the second dielectric layer;
eroding the third dielectric layer to create a patterned etch mask, the patterned etch mask being formed from the two interdigitized features in the second dielectric layer and sidewalls which are formed in the incompletely eroded third dielectric layer, the sidewalls sloping downward from a top of the second dielectric layer to define a narrow channel over the semiconductor layer; and
etching the semiconductor layer to produce a narrow etched channel, a width of the narrow etched channel being defined by the patterned etch mask, the width of the narrow etched channel further being less than a width of the substantially serpentine channel etched in the second dielectric layer.

2. The method of claim 1 further comprising:
removing the third dielectric layer; and
removing the second dielectric layer.

3. The method of claim 1 further comprising:
etching a region of the first dielectric layer, the region of the first dielectric layer to be etched being defined by the narrow etched channel.

4. The method of claim 1 further comprising:
forming a fourth dielectric layer over the second dielectric layer thereby substantially filling the narrow etched channel.

5. The method of claim 1 wherein a width of the substantially serpentine channel is substantially a minimum width attainable using photolithography.

6. The method of claim 1 wherein the substrate is comprised of silicon.

7. The method of claim 1 wherein the substrate is comprised of silicon germanium.

8. The method of claim 1 wherein the semiconductor layer is comprised of a compound semiconductor.

9. A memory cell device comprising:
a substrate;
a source region having a first doped region, the first doped region having a first type of majority carrier;
a drain region having a second doped region, the second doped region having the first type of majority carrier;
a channel region being coupled to the source region and the drain region, and doped with a second type of majority carrier;
a floating gate region, the floating gate region being coupled to the channel region by a gate oxide, the floating gate region further comprising a first plate of a capacitor; and
a control gate region, the control gate region including a second plate of the capacitor, the second plate of the capacitor being separated from the first plate of the capacitor by a narrow substantially serpentine channel, the narrow substantially serpentine channel being defined by conformally filling a substantially serpentine channel with a spacer dielectric and anisotropically etching the spacer dielectric leaving dielectric spacers along the substantially serpentine channel, a width of the narrow substantially serpentine channel being less than a limit of resolution of a photolithographic technique.

10. A method of fabricating a floating gate memory cell device, the method comprising:
forming a source region, the source region being doped with a first dopant having a first type of majority carrier;
forming a drain region, the drain region being doped with a second dopant, the second dopant supporting the first type of majority carrier;
forming a floating gate region, the floating gate region having a third dopant, the third dopant supporting a majority carrier of opposite polarity to the first type of majority carrier, the floating gate comprising a first plate of a capacitor; and
forming a control gate region, the control gate region comprising a second plate of the capacitor, the second plate of the capacitor being separated from the first plate of the capacitor by a narrow substantially serpentine channel, the narrow substantially serpentine channel being defined by conformally filling a substantially serpentine channel with a spacer dielectric and anisotropically etching the spacer dielectric leaving dielectric spacers along the substantially serpentine channel, a width of the narrow substantially serpentine channel being less than a limit of resolution of a photolithographic technique.

11. A method of fabricating a capacitor, the method comprising:
forming a semiconductor layer over an insulative substrate;
forming a first dielectric layer over the semiconductor layer;
etching the first dielectric layer to produce a substantially serpentine channel that extends through the first dielectric layer, the substantially serpentine channel creating two interdigitized features in the first dielectric layer;
depositing a second dielectric layer over the first dielectric layer to fill the substantially serpentine channel, the second dielectric layer having an etch rate dissimilar to an etch rate of the first dielectric layer;
eroding the second dielectric layer to create a patterned etch mask having sidewalls that slope downward from a top of the first dielectric layer to the semiconductor layer; and
etching the semiconductor layer to produce a narrow etched channel, a width of the narrow etched channel being defined by the patterned etch mask, the width of the narrow etched channel further being less than a width of the substantially serpentine channel etched in the first dielectric layer.

12. The method of claim 11 further comprising:
removing the second dielectric layer; and
removing the first dielectric layer.

13. The method of claim 11 wherein the width of the serpentine channel is substantially a minimum width attainable using photolithographic masking and etching techniques.

14. The method of claim 11, wherein the substrate is comprised of quartz.

15. The method of claim 11, wherein the substrate is comprised of glass.

16. The method of claim 11 wherein the semiconductor layer is comprised of a compound semiconductor.

17. A method for fabricating a capacitor, the method comprising:
providing a substrate including a semiconductor layer formed over an insulating layer;
forming a first dielectric layer over the semiconductor layer;
etching the first dielectric layer to produce a substantially serpentine channel that extends through the first dielectric layer, the substantially serpentine channel creating two interdigitized features in the first dielectric layer;
depositing a second dielectric layer over the first dielectric layer to fill the substantially serpentine channel, the second dielectric layer having an etch rate dissimilar to an etch rate of the first dielectric layer;
eroding the second dielectric layer to create a patterned etch mask having sidewalls that slope downward from a top of the first dielectric layer to the semiconductor layer; and
etching the semiconductor layer to produce a narrow etched channel, a width of the narrow etched channel being defined by the patterned etch mask, the width of the narrow etched channel further being less than a width of the substantially serpentine channel etched in the first dielectric layer.

18. The method of claim 17 wherein the substrate is silicon-on-insulator (SOI).

19. The method of claim 17 further comprising:
removing the second dielectric layer; and
removing the first dielectric layer.

20. The method of claim 17 further comprising:
forming a third dielectric layer over the second dielectric layer, substantially filling the narrow etched channel.

21. The method of claim 17 wherein a width of the substantially serpentine channel is substantially a minimum width attainable using photolithography.

22. A method for fabricating an integrated circuit device, the method comprising:
providing a semiconductor wafer with an implanted oxide layer (SIMOX);
forming a first dielectric layer over the semiconductor layer;
etching the first dielectric layer to produce a substantially serpentine channel that extends through the first dielectric layer, the substantially serpentine channel creating two interdigitized features in the first dielectric layer;
depositing a second dielectric layer over the first dielectric layer to fill the substantially serpentine channel, the second dielectric layer having an etch rate dissimilar to an etch rate of the first dielectric layer;
eroding the second dielectric layer to create a patterned etch mask, the patterned etch mask being formed from the two interdigitized features in the first dielectric layer and sidewalls which are formed in the incompletely eroded second dielectric layer, the sidewalls sloping downward from a top of the first dielectric layer to define a narrow channel over the semiconductor layer; and
etching the semiconductor layer to produce a narrow etched channel, a width of the narrow etched channel being defined by the patterned etch mask, the width of the narrow etched channel further being less than a width of the substantially serpentine channel etched in the first dielectric layer.

23. The method of claim 22 further comprising:
removing the second dielectric layer; and
removing the first dielectric layer.

24. The method of claim 22 further comprising:
etching the implanted oxide layer, a region of the implanted oxide layer to be etched being defined by the narrow etched channel.

25. The method of claim 22 further comprising:
forming a third dielectric layer over the second dielectric layer, substantially filling the narrow etched channel.

26. The method of claim 22 wherein a width of the substantially serpentine channel is substantially a minimum width attainable using photolithography.
